(19) United States
(12) Patent Application Publication
(10) Pub. No.: US 2020/0412042 A1
(43) Pub. Date: Dec. 31, 2020

(54) NETWORK INTERFACE CARD

(71) Applicants: Inventec (Pudong) Technology Corporation, Shanghai (CN); INVENTEC CORPORATION, Taipei (TW)

(72) Inventors: Xiu-Hua ZHAO, Shanghai (CN); Guo Jhen Huang, Taipei (TW)

(21) Appl. No.: 16/541,350

(22) Filed: Aug. 15, 2019

(30) Foreign Application Priority Data
Jun. 25, 2019 (CN) 201910555423.2

(51) Int. Cl. H01R 12/73; H01L 23/367; H01R 12/72; H05K 1/18; H05K 1/02; H05K 1/14

(52) U.S. Cl. CPC H01R 12/73; H01L 23/367; H01R 12/721; H01R 12/722; H05K 2201/066; H05K 1/0203; H05K 1/14; H05K 2201/10189; H05K 1/181

(57) ABSTRACT

This disclosure relates to a network interface card includes a first interface card. The first interface card includes a first circuit board and a first connector. The first connector is disposed on the first circuit board. The first circuit board includes a plurality of connection terminals with longitudinal axes in different directions from the first connector. The first connector is a board-to-board connector.

### CROSS-REFERENCE TO RELATED APPLICATIONS

This non-provisional application claims priority under 35 U.S.C. § 119(a) on Patent Application No(s). 201910555423.2 filed in China, P.R.C. on Jul. 25, 2019, the entire contents of which are hereby incorporated by reference.

### TECHNICAL FIELD

The present disclosure relates to a network interface card, more particularly to a network interface card including a board-to-board connector.

### BACKGROUND

As the technology develops, the electronic devices have a rapid growth in demand for network transmission speed. There have been developed software-defined networking (SDN) and virtualization technology to improve network speed and the usage of hardware resources as the hardware devices did not have a breakthrough yet. And there has been a conventional smart network interface card (Smart NIC) that has capability of edge computing and is able to improve network access response times of hardware.

### SUMMARY

According to one aspect of the present disclosure, a network interface card includes a first interface card. The first interface card includes a first circuit board and a first connector. The first connector is disposed on the first circuit board. The first circuit board includes a plurality of connection terminals with longitudinal axes in different directions from the first connect. The first connector is a board-to-board connector.

According to another aspect of the present disclosure, a network interface card includes a first interface card and a second interface card. The first interface card includes a first circuit board and a first connector. The first connector is disposed on the first circuit board. The first circuit board includes a plurality of connection terminals with longitudinal axes in different directions from the first connect. The second interface card includes a second circuit board and a second connector. The second connector is disposed on the second circuit board. The second interface card is detachably disposed on and electrically connected to the first connector. The first connector is a board-to-board connector.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a perspective view of a network interface card according to one embodiment of the present disclosure;

FIG. 2 is an exploded view of the network interface card in FIG. 1;

FIG. 3 is a perspective view of a network interface card according to another embodiment of the present disclosure;

FIG. 4 is an exploded view of the network interface card in FIG. 3;

FIG. 5 is an exploded view of part of the network interface card in FIG. 3;

FIG. 6 is a schematic view showing an assembly process of part of the network interface card in FIG. 3; and

FIG. 7 is a schematic view showing an assembly process of the network interface card in FIG. 3.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

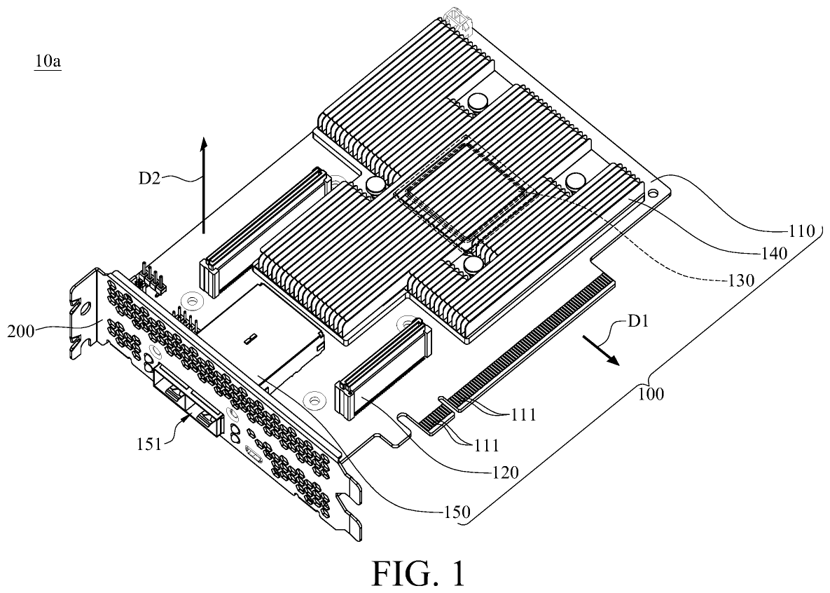

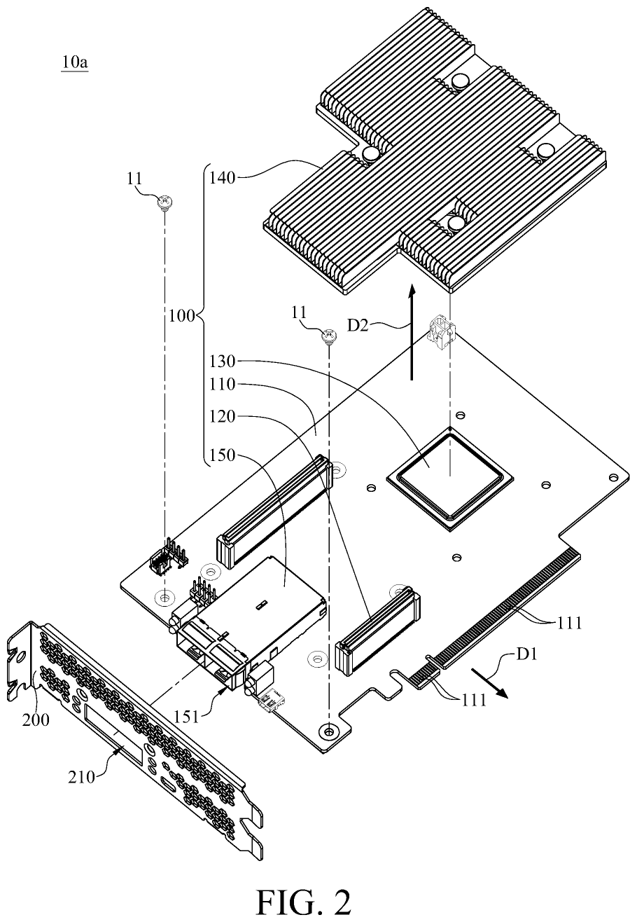

Please refer to FIG. 1 and FIG. 2, where FIG. 1 is a perspective view of a network interface card 10a according to one embodiment of the present disclosure, and FIG. 2 is an exploded view of the network interface card 10a in FIG. 1.

In this embodiment, the network interface card 10a is, for example, an improved smart network interface card (smart NIC) conforming to the specifications of peripheral component interconnect express x16 (PCI-e x16). The network interface card 10a, for example, is applicable to software-defined networking (SDN) and virtualization technology so as to improve network access response times of hardware. The network interface card 10a is installed to, for example, a large-scale server (not shown). The network interface card 10a is able to perform edge computing to share the burden of the CPU of the server.

The network interface card 10a includes a first interface card 100. The first interface card 100 includes a first circuit board 110 and a first connector 120. The first circuit board 110 has a size of, for example, approximately 167.65 millimeters (mm)×111.15 mm. The first connector 120 is disposed on and electrically connected to the first circuit board 110. The first circuit board 110 includes a plurality of connection terminals 111. The connection terminals 111 are, for example, gold fingers or edge connectors. The connection terminals 111 each have a longitudinal axis D1, and the first connector 120 extends toward a direction D2 which is different from the longitudinal axis D1 of the connection terminal 111. The connection terminals 111 of the first interface card 100 can be inserted into a motherboard of the server along the longitudinal axis D1. That is, the insertion direction of the first interface card 100 is parallel to the longitudinal axis D1. The first connector 120 is a board-to-board connector. Therefore, the first connector 120 can be inserted into another interface card along the direction D2, such that the first interface card 100 can be easily and quickly connected to another interface card to improve the overall capability of edge computing.

In detail, in this and some embodiment of the present disclosure, the first interface card 100 may further include a first chip 130 and a first heatsink 140. The first chip 130 and the first heatsink 140 are both disposed on the first circuit board 110. The first chip 130 is located between the first heatsink 140 and the first circuit board 110 and is electrically connected to the first connector 120. The first chip 130 is a processing center of the first interface card 100. The first heatsink 140 has a thermal conductivity higher than that of the first chip 130. The first heatsink 140 is able to absorb heat generated by the first chip 130 so as to prevent the first interface card 100 from being damaged due to overheating.

In this and some embodiment of the present disclosure, the network interface card 10a may further include a cover plate 200. The first interface card 100 is disposed to the cover plate 200 by, for example, screws 11. The network interface card 10a may be disposed to the server by, for example, screwing the cover plate 200 to the casing of the server. The first interface card 100 may further include a communication connector 150. The communication connector 150 is disposed on the first circuit board 110 and connected to a side of the cover plate 200. The cover plate 200 has a through hole 210. The communication connector 150 may further have a port 151 connected to the through hole 210 of the cover plate 200 so as to be exposed to the outside of the server. The network interface card 10a can be electrically connected to various external devices through the communication connector 150, such that the network interface card 10a is applicable to various occasions. In addition, the first connector 120, the first chip 130, the first heat sink 140 and the communication connector 150 are modularized onto the first circuit board 110 so that the first interface card 100 is easily to be assembled to the cover plate 200.

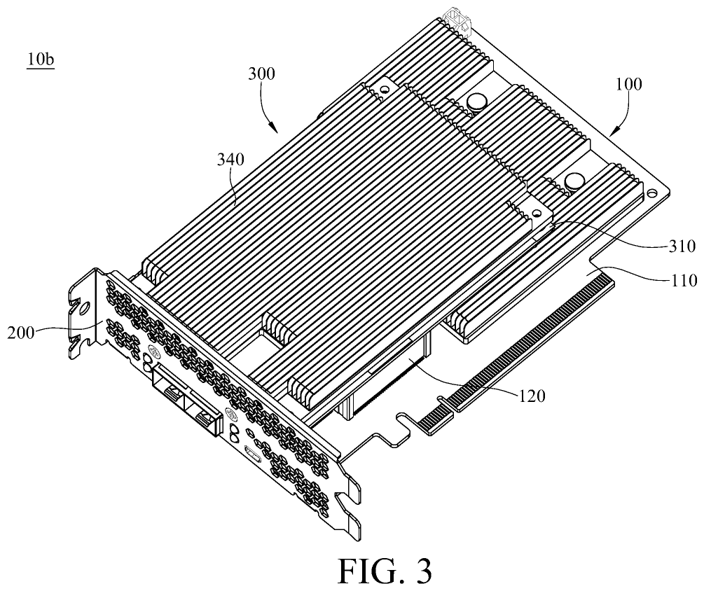

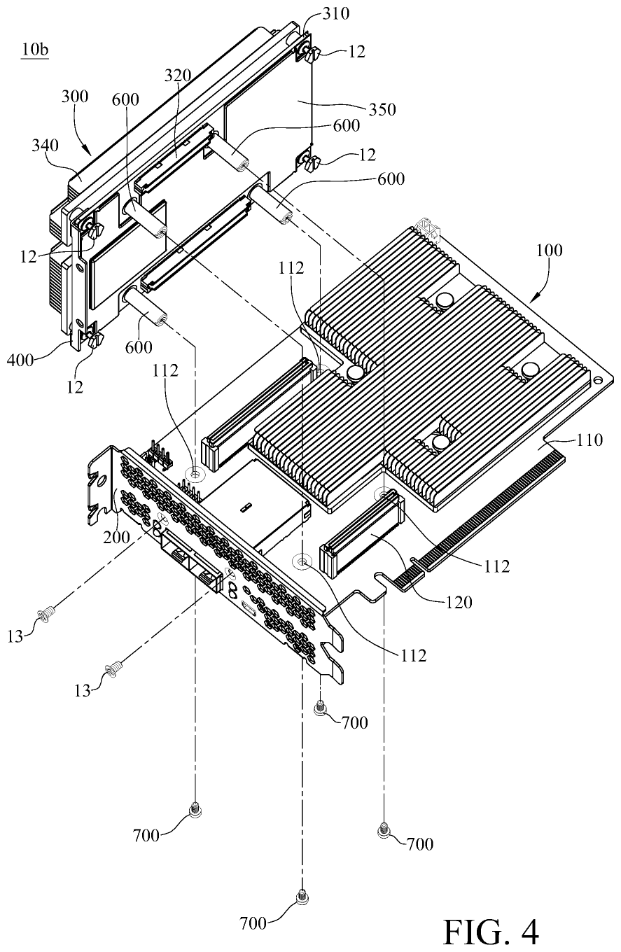

Please refer to FIG. 3 and FIG. 4, where FIG. 3 is a perspective view of a network interface card 10b according to another embodiment of the present disclosure, and FIG. 4 is an exploded view of the network interface card 10b in FIG. 3. Only the differences between this and the previous embodiments are illustrated hereinafter. In this and some embodiments of the present disclosure, the network interface card 10b is, for example, an improved smart network interface card conforming to open compute project (OCP).

In this and some embodiments of the present disclosure, the network interface card 10b may further include a second interface card 300. The second interface card 300 includes a second circuit board 310 and a second connector 320. The second connector 320 is disposed on and electrically connected to the second circuit board 310. The second connector 320 is a board-to-board connector and can be inserted into the first connector 120. The second interface card 300 may be the another interface card in the aforementioned embodiment for the first interface card 100 to be connected thereto. The second interface card 300 can be detachably disposed on and electrically connected to the first interface card 100 through the first connector 120 and the second connector 320. The first interface card 100 and the second interface card 300 are able to perform different computing tasks at the same time so as to further improve the capability of edge computing of the network interface card 10b.

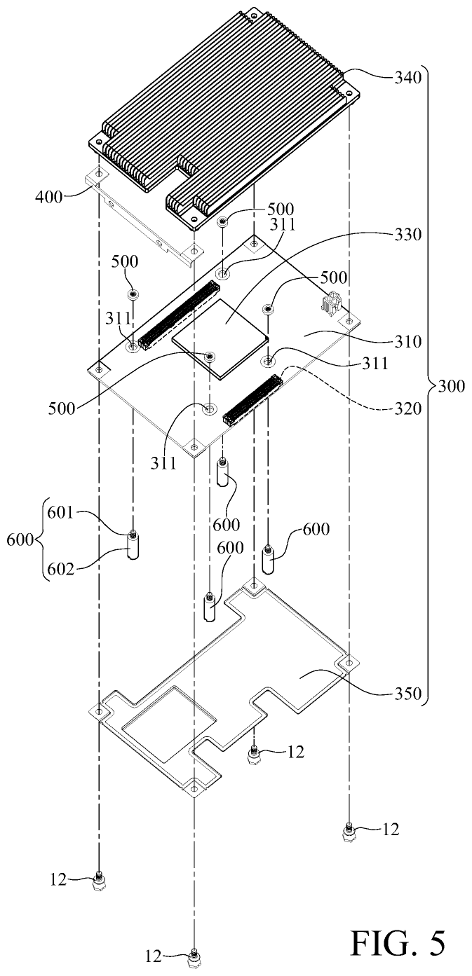

Please refer to FIG. 5 together to further describe the second interface card 300, wherein FIG. 5 is an exploded view of part of the network interface card 10b in FIG. 3.

In this and some embodiment of the present disclosure, the second interface card 300 may further include a second chip 330 and a second heatsink 340. The second chip 330 and the second heatsink 340 are both disposed on the second circuit board 310. The second chip 330 is located between the second heatsink 340 and the second circuit board 310 and is electrically connected to the second connector 320. The second chip 330 is a processing center of the second interface card 300. The second heatsink 340 is able to absorb heat generated by the second chip 330 so as to prevent the second interface card 300 from being damaged due to overheating.

In this and some embodiment of the present disclosure, the second interface card 300 may further include a back plate 350. The back plate 350 is disposed on the second circuit board 310 and located between the first circuit board 110 and the second circuit board 310. As such, the back plate 350 is able to protect the second circuit board 310 from directly hitting the first interface card 100 and to prevent dust from entering the second circuit board 310.

In this and some embodiment of the present disclosure, the network interface card 10b may further include a bracket 400. The second interface card 300 is detachably disposed to the bracket 400 by, for example, screws 12. The second interface card 300 is detachably disposed to the cover plate 200 by, for example, screwing the bracket 400 to the cover plate 200 through screws 13. In this way, the cover plate 200 is able to share the weight of the second interface card 300 through the bracket 400 so as to prevent the second interface card 300 from directly loading on the first connector 120. In addition, the second connector 320, the second chip 330, the second heatsink 340 and the back plate 350 are modularized onto the second circuit board 310 so that the second interface card 300 is easily to be assembled to the first interface card 100 and the bracket 400.

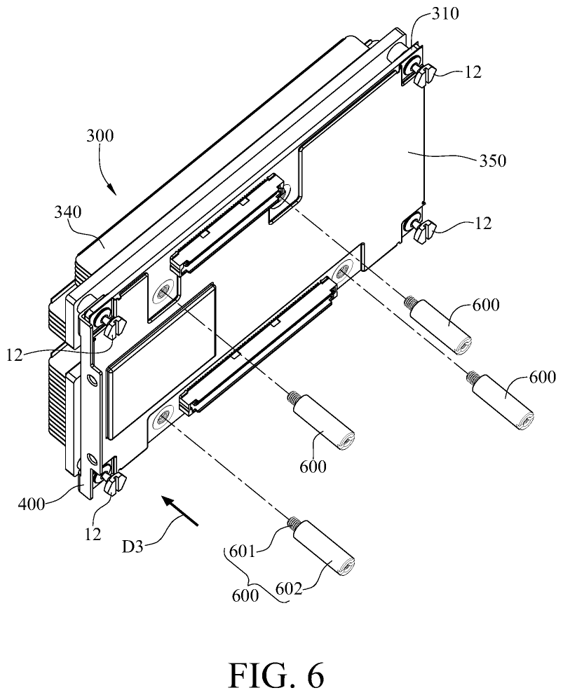

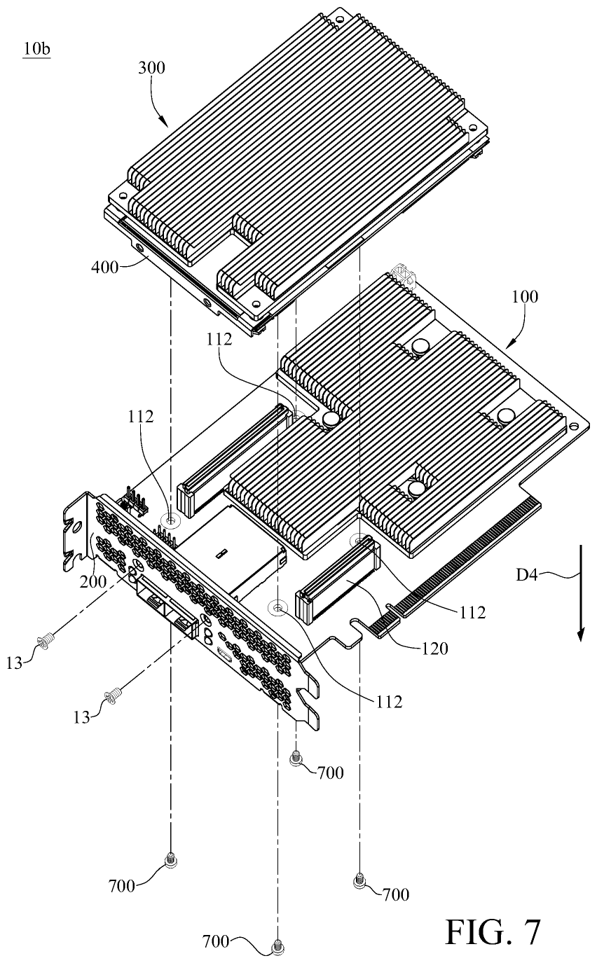

Please refer to FIG. 4 to FIG. 7 to describe assembly processes of the network interface card 10b in detail, wherein FIG. 6 is a schematic view showing an assembly process of part of the network interface card 10b in FIG. 3, and FIG. 7 is a schematic view showing an assembly process of the network interface card 10b in FIG. 3.

In this and some embodiment of the present disclosure, the network interface card 10b may further include four nuts 500, four fasteners 600 and four screws 700. The first circuit board 110 may further have four first openings 112. The second circuit board 310 may further have four second openings 311. The nuts 500 are, for example, soldered to the second circuit board 310, and the nuts 500 are respectively connected to the second openings 311. The fasteners 600 are, for example, studs and each have a first end 601 and a second end 602 opposite to each other. The fasteners 600 each have external threads matching the nuts 500 at the first end 601. The first end 601 has a diameter smaller than the diameter of the first opening 112, the diameter of the second opening 311 and the outer diameter of the nut 500. The fasteners 600 each have internal threads matching the screws 700 at the second end 602. The second end 602 has a diameter larger than the diameter of the first opening 112, the diameter of the second opening 311 and the diameter of the threads part of the screw 700.

In the process of assembling the network interface card 10b, the first step may be to insert the first end 601 of the fastener 600 into the second opening 311 in a direction D3 from the side of the second circuit board 310 where the second connector 320 is disposed and then to screw the first end 601 into the nut 500, such that the fastener 600 can be fixed to the second circuit board 310. Then, the second step may be to connect the second connector 320 of the second interface card 300 to the first connector 120 of the first interface card 100 along a direction D4 so as to assemble the second interface card 300 to the first interface card 100. Meanwhile, the second end 602 of the fastener 600 is aligned with the first opening 112. Then, the next step may be to insert the screw 700 into the first opening 112 from the side of the first circuit board 110 opposite to the first connector 120 and then to screw the screw 700 into the second end 602 of the fastener 600. By doing so, the second interface card 300 can be fixed to the first interface card 100, and the structural connection between the first interface card 100 and the second interface card 300 is improved, such that the second connector 320 is prevented from detaching from the first connector 120 due to vibration. Then, as mentioned above, the second interface card 300 may be detachably disposed to the cover plate 200 by, for example, screwing the bracket 400 to the cover plate 200 through the screws 13. Here are the assembly processes of the network interface card 10b, and then the network interface card 10b may be disposed to the server by, for example, screwing the cover plate 200 to the casing of the server.

According to the network interface card discussed above, since the first connector is a board-to-board connector, the first interface card can be easily and quickly connected to another interface card via the first connector so as to improve the overall capability of edge computing.

In some embodiments, the first connector, the first chip, the first heat sink and the communication connector are modularized onto the first circuit board so that the first interface card is easily to be assembled to the cover plate.

In some embodiments, the second interface card can be electrically connected to the first connector through the first connector and the second connector. The first interface card and the second interface card are able to perform different computing tasks at the same time so as to further improve the capability of edge computing of the network interface card.

In some embodiments, the second connector, the second chip, the second heatsink and the back plate are modularized onto the second circuit board so that the second interface card is easy to be assembled to the first interface card and the bracket.

In some embodiments, the second interface card is detachably disposed to the cover plate by, for example, screwing the bracket to the cover plate through screws. In this way, the cover plate is able to share the weight of the second interface card through the bracket so as to prevent the second interface card from directly loading on the first connector.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

1. A network interface card, comprising:
a first interface card, comprising a first circuit board, a first connector and a communication connector, and the first connector and the communication connector being disposed on the first circuit board;
a cover plate, wherein the first interface card is disposed to the cover plate, the cover plate has a through hole, and the through hole exposes the communication connector; and
a second interface card, comprising a second circuit board and a second connector, wherein the second connector is disposed on the second circuit board, and the second connector is detachably disposed on and electrically connected to the first connector;
wherein, the first circuit board comprises a plurality of connection terminals with longitudinal axes in different directions from the first connector, and the first connector is a board-to-board connector.

2. The network interface card according to claim 1, wherein the first interface card further comprising a first chip and a first heatsink, the first chip is located between the first heatsink and the first circuit board and is electrically connected to the first connector.

3. (canceled)

4. (canceled)

5. The network interface card according to claim 1, further comprising a bracket, wherein the second interface card is detachably disposed to the cover plate via the bracket.

6. The network interface card according to claim 1, wherein the second interface card further comprises a back plate, the back plate is disposed on the second circuit board and located between the first circuit board and the second circuit board.

7. The network interface card according to claim 1, wherein the second interface card further comprises a second chip and a second heatsink, the second chip is located between the second heatsink and the second circuit board and is electrically connected to the second connector.

8. The network interface card according to claim 1, further comprising a fastener, a screw and a nut, wherein the first circuit board further has a first opening, the second circuit board further has a second opening, the fastener has an end with a diameter larger than a diameter of the first opening, a diameter of the second opening and a diameter of a thread part of the screw, the fastener further has another end with a diameter smaller than a diameter of the first opening, a diameter of the second opening and an outer diameter of the nut, the another end of the fastener is passed through the first opening or the second opening, and the fastener is clamped between the first circuit board and the second circuit board by the screw and the nut.

9. A network interface card, comprising:
by the cell temperature probe;
a first interface card, comprising a first circuit board and a first connector, the first connector being disposed on the first circuit board, the first circuit board comprising a plurality of connection terminals with longitudinal axes in different directions from the first connector; and
a second interface card, comprising a second circuit board and a second connector, the second connector being disposed on the second circuit board, the second connector being detachably disposed on and electrically connected to the first connector;
wherein, the first connector is a board-to-board connector.

10. The network interface card according to claim 9, further comprising a cover plate and a bracket, wherein the first interface card is disposed to the cover plate, and the second interface card is detachably disposed to the cover plate via the bracket.
